(19) United States
(12) Patent Application Publication
(10) Pub. No.: US 2025/0201309 A1
(43) Pub. Date: Jun. 19, 2025

(54) SYSTEMS, METHODS, AND MEDIA FOR RECOVERING NON-VOLATILE MEMORY DEVICES FROM POWER LOSS

(71) Applicant: SK hynix NAND Product Solutions Corporation, Rancho Cordova, CA (US)

(72) Inventors: Shankar Natarajan, Folsom, CA (US); Yihua Zhang, Folsom, CA (US); Sriram Natarajan, Folsom, CA (US)

(21) Appl. No.: 18/540,464

(22) Filed: Dec. 14, 2023

(51) Int. Cl. G11C 16/08

(52) U.S. Cl. CPC G11C 16/08

(57) ABSTRACT

Mechanisms for recovering NVM devices from power loss including: identifying a first last valid written page (LVWP) of a first block of the NVM device; identifying a first first empty page (FEP) after the first LVWP of the first block; determining that no pages exist between the first LVWP and the first FEP using a hardware processor; and in response to determining that no pages exist between the first LVWP and the first FEP, indicating that the first block can be used. In some embodiments, the mechanisms further comprise: identifying a second LVWP of a second block of the NVM device; identifying a second FEP after the second LVWP of the second block; determining that pages exist between the second LVWP and the second FEP; and in response to determining that pages exist between the second LVWP and the second FEP, performing a recovery process on the second block.

### BACKGROUND

Non-volatile memory (NVM) devices, such as flash memory devices, NAND flash memory devices, and solid-state drives (SSDs) (e.g., including drives based on NAND flash memory devices, other forms of flash memory, and/or other forms of NVM), are widely used in a variety of computing devices. Typically, when such devices are implemented without power backup mechanisms that can gracefully shutdown the devices when main power is lost, recovery can require re-writing entire blocks of data that were partially written at the time of the power loss. Re-writing entire blocks of data can delay or slow normal use of the NVM devices.

Accordingly, new mechanisms for recovering NVM devices from power loss are desirable.

### SUMMARY

In accordance with some embodiments, mechanisms (which can include systems, methods, and media) for recovering NVM devices from power loss are provided.

In some embodiments, systems for recovering a non-volatile memory (NVM) device from a power loss are provided, the system comprising: memory; and at least one hardware processor coupled to the memory and collectively configured to at least: identify a first last valid written page (LVWP) of a first block of the NVM device; identify a first first empty page (FEP) after the first LVWP of the first block; determine that no pages exist between the first LVWP and the first FEP; and in response to determining that no pages exist between the first LVWP and the first FEP, indicate that the first block can be used. In some of these embodiments, the at least one hardware processor is further configured to: identify a second LVWP of a second block of the NVM device; identify a second FEP after the second LVWP of the second block; determine that pages exist between the second LVWP and the second FEP; and in response to determining that pages exist between the second LVWP and the second FEP, perform a recovery process on the second block. In some of these embodiments, the recovery process comprises: restoring the second block to a last known good state; and invalidating a given non-zero number word lines of the second block after a last word line of the last known good state. In some of these embodiments, the recovery process further comprises reconstructing data of non-empty pages of the second block after the last page of the last known good state. In some of these embodiments, the recovery process comprises migrating all data from a first page of the second block through to and including the LVWP of the second block to a new data block. In some of these embodiments, the recovery process comprises: invalidating a first given non-zero number of word lines of the second block prior to and including a last page before the FEP; and dummy programming a second given non-zero number of word lines of the second block starting at the FEP. In some of these embodiments, the recovery process further comprises: reading pages of the second block; determining that at least a threshold number of read errors are encountered on valid word lines of the second block; and creating a new block of data to replace the second block.

In some embodiments, methods for recovering a non-volatile memory (NVM) device from a power loss are provided, the methods comprising: identifying a first last valid written page (LVWP) of a first block of the NVM device; identifying a first first empty page (FEP) after the first LVWP of the first block; determining that no pages exist between the first LVWP and the first FEP using a hardware processor; and in response to determining that no pages exist between the first LVWP and the first FEP, indicating that the first block can be used. In some of these embodiments, the methods further comprise: identifying a second LVWP of a second block of the NVM device; identifying a second FEP after the second LVWP of the second block; determining that pages exist between the second LVWP and the second FEP; and in response to determining that pages exist between the second LVWP and the second FEP, performing a recovery process on the second block. In some of these embodiments, the recovery process comprises: restoring the second block to a last known good state; and invalidating a given non-zero number word lines of the second block after a last word line of the last known good state. In some of these embodiments, the recovery process further comprises reconstructing data of non-empty pages of the second block after the last page of the last known good state. In some of these embodiments, the recovery process comprises migrating all data from a first page of the second block through to and including the LVWP of the second block to a new data block. In some of these embodiments, the recovery process comprises: invalidating a first given non-zero number of word lines of the second block prior to and including a last page before the FEP; and dummy programming a second given non-zero number of word lines of the second block starting at the FEP. In some of these embodiments, the recovery process further comprises: reading pages of the second block; determining that at least a threshold number of read errors are encountered on valid word lines of the second block; and creating a new block of data to replace the second block.

In some embodiments, non-transitory computer-readable media containing computer executable instructions that, when executed by a processor, cause the processor to perform a method for recovering a non-volatile memory (NVM) device from a power loss are provided, the method comprising: identifying a first last valid written page (LVWP) of a first block of the NVM device; identifying a first first empty page (FEP) after the first LVWP of the first block; determining that no pages exist between the first LVWP and the first FEP; and in response to determining that no pages exist between the first LVWP and the first FEP, indicating that the first block can be used. In some of these embodiments, the method further comprises: identifying a second LVWP of a second block of the NVM device; identifying a second FEP after the second LVWP of the second block; determining that pages exist between the second LVWP and the second FEP; and in response to determining that pages exist between the second LVWP and the second FEP, performing a recovery process on the second block. In some of these embodiments, the recovery process comprises: restoring the second block to a last known good state; and invalidating a given non-zero number word lines of the second block after a last word line of the last known good state. In some of these embodiments, the recovery process further comprises reconstructing data of non-empty pages of the second block after the last page of the last known good state. In some of these embodiments, the recovery process comprises migrating all data from a first page of the second block through to and including the LVWP of the second block to a new data block. In some of these embodiments, the recovery process comprises: invalidating a first given non-zero number of word lines of the second block prior to and including a last page before the FEP; and dummy programming a second given non-zero number of word lines of the second block starting at the FEP. In some of these embodiments, the recovery process further comprises: reading pages of the second block; determining that at least a threshold number of read errors are encountered on valid word lines of the second block; and creating a new block of data to replace the second block.

### BRIEF DESCRIPTION OF THE DRAWINGS

FIG. 1 is a block diagram of an example of a solid-state drive (SSD) coupled to a host device via a bus in accordance with some embodiments.

FIG. 2 is an illustration of an example of a process for recovering a system block of an SSD in accordance with some embodiments.

FIG. 3 is an illustration of an example of a process for recovering a host-write data block of an SSD in accordance with some embodiments.

FIG. 4 is an illustration of an example of a process for recovering a migration data block of an SSD in accordance with some embodiments.

FIG. 5 is a flow diagram of a process for recovering an SSD from a power loss in accordance with some embodiments.

### DETAILED DESCRIPTION

In accordance with some embodiments, mechanisms (which can include systems, methods, and media) for recovering NVM devices from power loss are provided. Non-volatile memory (NVM) devices can include flash memory devices, NAND flash memory devices (e.g., multi-plane NAND memory, 3D NAND, memory with any of the following memory densities: single-level cells (SLCs), multilevel cells (MLCs), triple-level cells (TLCs), quad-level cells (QLCs), penta-level cells (PLCs), and any suitable memory density that is greater than five bits per memory cell, and/or any other suitable NAND flash memory), NOR flash memory devices, phase change memory, solid-state drives (SSDs) (e.g., including drives based on NAND flash memory devices, NOR flash memory devices, other forms of flash memory, phase change memory, and/or other forms of NVM), Serial Peripheral Interface (SPI) storage, and/or any other suitable device with non-volatile writable memory.

In some embodiments, upon recovery from a power loss, the mechanisms described herein check each open block of an NVM device to identify the last valid written page (LVWP) and the first empty page (FEP) after the LVWP. If there are no pages between the LVWP and the FEP, the block will be left as is and used normally (in this case, it can be assumed that there are no invalid pages between the LVWP and the FEP). If there are one or more pages between the LVWP and the FEP (in which case it can be assumed that all pages between the LVWP and the FEP are invalid), the mechanisms will take a different action based on whether the block is a system block (which may also be referred to as a “meta block”; i.e., a block that stores metadata (and of any other suitable information) used by the NVM device) with checkpoints, a host-write data block (i.e., a block being written to by a host at the time of a power loss), or a migration data block (i.e., a block being written to with data being migrated from another block, such as a cache block).

For a system block with one or more checkpoints, in some embodiments, the mechanisms described herein can restore the block to the last known good state, invalidate N word lines after the checkpoint, and reconstruct the data of the non-empty pages by scanning data blocks of the NVM device. Any suitable value for N (including one and zero) can be used in some embodiments, and this value can be technology dependent. For example, in some embodiments, N can be 3, 4, 5, 6, 7, or 8.

For a host-write data block, the mechanisms described herein can migrate all data from the first page through to and including the L VWP to a new data block.

For a migration data block, the mechanisms can: invalidate X word lines (WLs) of the block prior to the WL including the page immediately after the LVWP; invalidate all pages between the LVWP and the FEP; dummy program any empty pages in the WL including the last page before the FEP; and dummy program Y WLs of the block after the WL including the last page before the FEP. Any suitable values for X and Y (including one and zero) can be used in some embodiments, and these values can be technology dependent. For example, in some embodiments, X can be 3, 4, 5, 6, 7, or 8 and Y can be 3, 4, 5, 6, 7, or 8. In some embodiments, to subsequently confirm reliability of the block, all or a subset of all of the pages of the block can be read, and if any suitable number of read errors are encountered on valid WLs, the block can be abandoned and the original source copy of retained to potentially be migrated later.

By reducing the amount of data re-written upon recovery of an NVM device from a power loss, the mechanisms described herein reduce delays associated with power recovery and therefore improve the performance of the NVM device.

Some embodiments are described below in connection with solid-stated drive (SSDs). It should be understood that the mechanisms described herein can be applied to other forms of NVM devices besides SSDs. For example, the mechanisms described here in can be applied to flash memory, such as NAND flash memory.

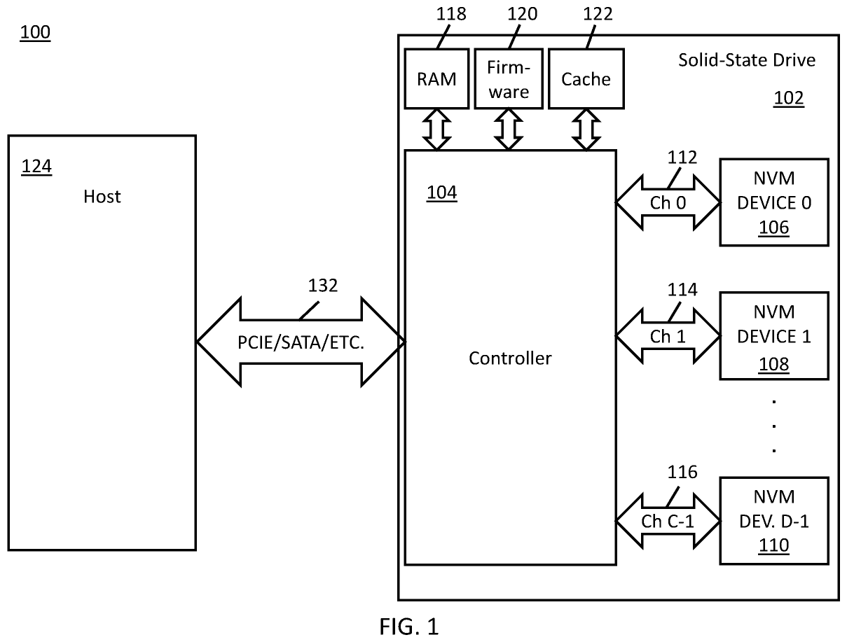

Turning to FIG. 1, an example block diagram of a solid-state drive 102 coupled to a host device 124 via a bus 132 in accordance with some embodiments is illustrated.

As shown, solid-state drive 102 can include a controller 104, non-volatile memory (NVM) devices 106, 108, and 110, channels 112, 114, and 116, random access memory (RAM) 118, firmware 120, and cache 122 in some embodiments. In some embodiments, more or fewer components (e.g., NVM devices and/or channels) than shown in FIG. 1 can be included. In some embodiments, two or more components shown in FIG. 1 can be included in one component.

Controller 104 can be any suitable controller for a solid-state drive in some embodiments. In some embodiments, controller 104 can include any suitable hardware processor(s) (such as a microprocessor, a digital signal processor, a microcontroller, a programmable gate array, etc.). In some embodiments, controller 104 can also include any suitable memory (such as RAM, firmware, cache, buffers, latches, etc.), interface controller(s), interface logic, drivers, etc.

NVM devices 106, 108, and 110 can be any suitable NVM devices for storing information (which can include data, programs, and/or any other suitable information that can be stored in a solid-state drive) in some embodiments. The NVM devices can include any suitable memory cells, hardware processor(s) (such as a microprocessor, a digital signal processor, a microcontroller, a programmable gate array, etc. devices), interface controller(s), interface logic, drivers, etc. in some embodiments. While three NVM devices (106, 108, and 110) are shown in FIG. 1, any suitable number D of NVM devices (including only one) can be used in some embodiments. Any suitable type of NVM devices can be used, such as NAND devices (e.g., multi-plane NAND memory, 3D NAND, memory with any of the following memory densities: single-level cells (SLCs), multilevel cells (MLCs), triple-level cells (TLCs), quad-level cells (QLCs), penta-level cells (PLCs), and any suitable memory density that is greater than five bits per memory cell, and/or any other suitable memory) in some embodiments. Each NVM device can have any suitable size in some embodiments. As noted above, in some embodiments, devices 106, 108, and 110 can be NAND devices, however, the devices can additionally or alternatively use any other suitable storage technology or technologies, such as NOR flash memory or any other suitable flash technology, phase change memory technology, and/or other any other suitable non-volatile memory storage technology.

Channels 112, 114, and 116 can be any suitable mechanism for communicating information between controller 104 and NVM device 106, 108, and 110 in some embodiments. For example, the channels can be implemented using conductors (lands) on a circuit board in some embodiments. While three channels (112, 114, and 116) are shown in FIG. 1, any suitable number C of channels can be used in some embodiments.

Random access memory (RAM) 118 can include any suitable type of RAM, such as dynamic RAM, static RAM, etc., in some embodiments. Any suitable number of RAM 118 can be included, and each RAM 118 can have any suitable size, in some embodiments.

Firmware 120 can include any suitable combination of software and hardware in some embodiments. For example, firmware 120 can include software programmed in any suitable programmable read only memory (PROM) in some embodiments. Any suitable number of firmware 120, each having any suitable size, can be used in some embodiments.

Cache 122 can be any suitable device for temporarily storing information (which can include data and programs in some embodiments), in some embodiments. Cache 122 can be implemented using any suitable type of device, such as RAM (e.g., static RAM, dynamic RAM, etc.) in some embodiments. Any suitable number of cache 122, each having any suitable size, can be used in some embodiments.

Host device 124 can be any suitable device that accesses stored information in some embodiments. For example, in some embodiment, host device 124 can be a general-purpose computer, a special-purpose computer, a desktop computer, a laptop computer, a tablet computer, a server, a database, a router, a gateway, a switch, a mobile phone, a communication device, an entertainment system (e.g., an automobile entertainment system, a television, a set-top box, a music player, etc.), a navigation system, etc. While only one host device 124 is shown in FIG. 1, any suitable number of host devices can be included in some embodiments.

Bus 132 can be any suitable bus for communicating information (which can include data and/or programs in some embodiments), in some embodiments. For example, in some embodiments, bus 132 can be a PCIE bus, a SATA bus, or any other suitable bus.

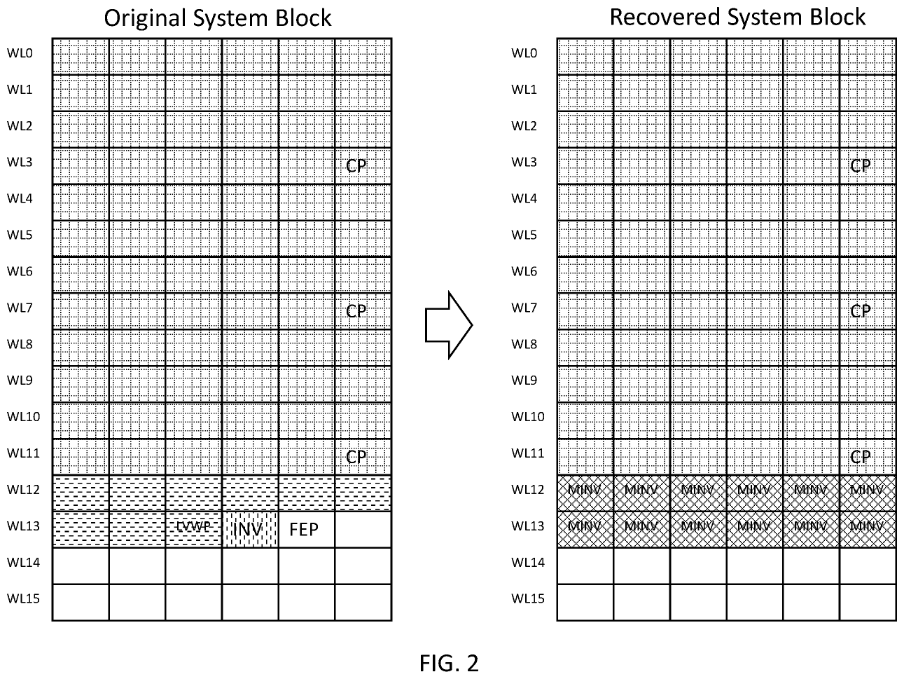

Turning to FIGS. 2-4, examples of how the mechanism described herein can act upon an open block with one or more invalid, non-empty pages upon power recovery of an NVM device (such as an SSD) are illustrated, in accordance with some embodiments. Although these figures show each block as including 16 word lines labelled WL0 through WL15, each having six pages (each box or cell is a page in these illustrations), a block can have any suitable number of word lines, each having any suitable number of pages.

FIG. 2 shows a power loss recovery for a system block having one or more invalid, non-empty pages. The block to the left of the arrow in the figure represents an original system block before recovery by embodiments of the mechanisms described herein, and the block to the right of the arrow in the figure represents the same system block after recovery (the recovered system block) by the mechanisms described herein.

As illustrated, upon restoration of power, the system block on the left contains 12 word lines (WL0 through WL11) of data that has been checkpointed, as represented by the three CPs in the block. The LVWP is represented by LVWP in the figure. The FEP is represented by FEP in the figure. An invalid page is represented by INV in the figure. Although only one invalid page is shown in FIG. 2, any number of invalid pages could be present between the LVWP and the FEP, in some embodiments. As can be seen, WL12 includes six valid written pages and WL13 includes three valid written pages, one invalid page, and two empty pages.

In recovering this system block, in some embodiments, as shown in the block on the right side of the arrow in FIG. 2, the mechanisms described herein can restore the block to the last known good state (i.e., WL11) and invalidate N word lines after the checkpoint as represented my MINV in the figure. Any suitable value for N (including one and zero) can be used in some embodiments, and this value can be technology dependent. For example, in some embodiments, N can be 3, 4, 5, 6, 7, or 8. Then, the data of any remaining non-empty pages of the original system block can be reconstructed by scanning data blocks of the NVM device and writing to the pages starting at the first available, empty WL (e.g., WL14 in the figure).

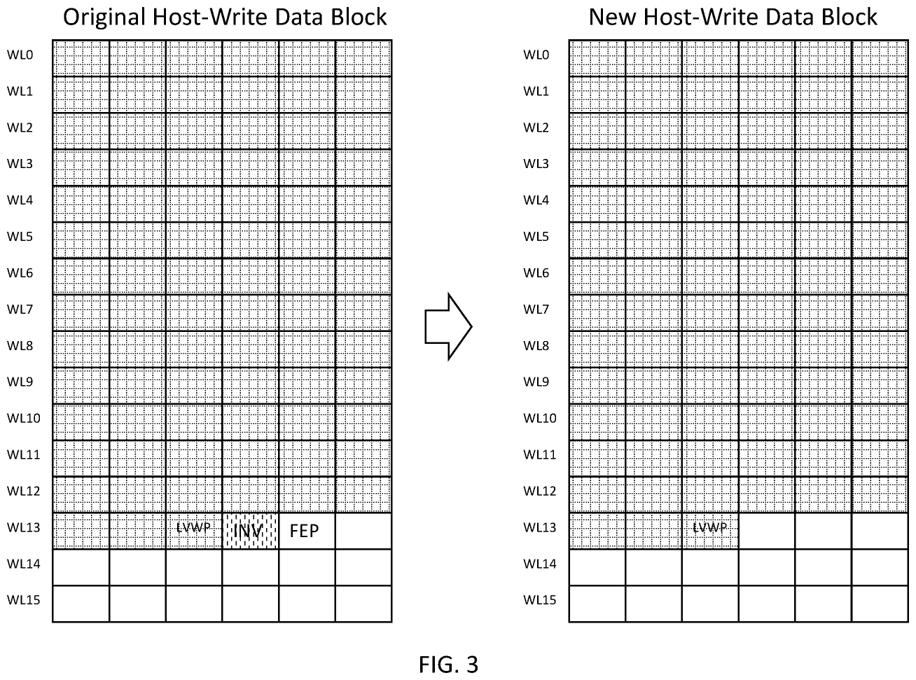

FIG. 3 shows a power loss recovery for a host-write data block having one or more invalid, non-empty pages. The block to the left of the arrow in the figure represents an original host-write data block before recovery by embodiments of the mechanisms described herein, and the block to the right of the arrow in the figure represents a new host-write data block after recovery by the mechanisms described herein.

As illustrated, upon restoration of power, the original host-write data block contains 13 word lines (WL0 through WL12) and three pages in WL13 of data that are valid. The LVWP is represented by LVWP in the figure. The FEP is represented by FEP in the figure. An invalid page is represented by INV in the figure. Although only one invalid page is shown in FIG. 3, any number of invalid pages could be present between the LVWP and the FEP, in some embodiments.

In recovering this host-write data block, the mechanisms described herein can migrate all data from the first page through to and including the LVWP to the new host-write data block.

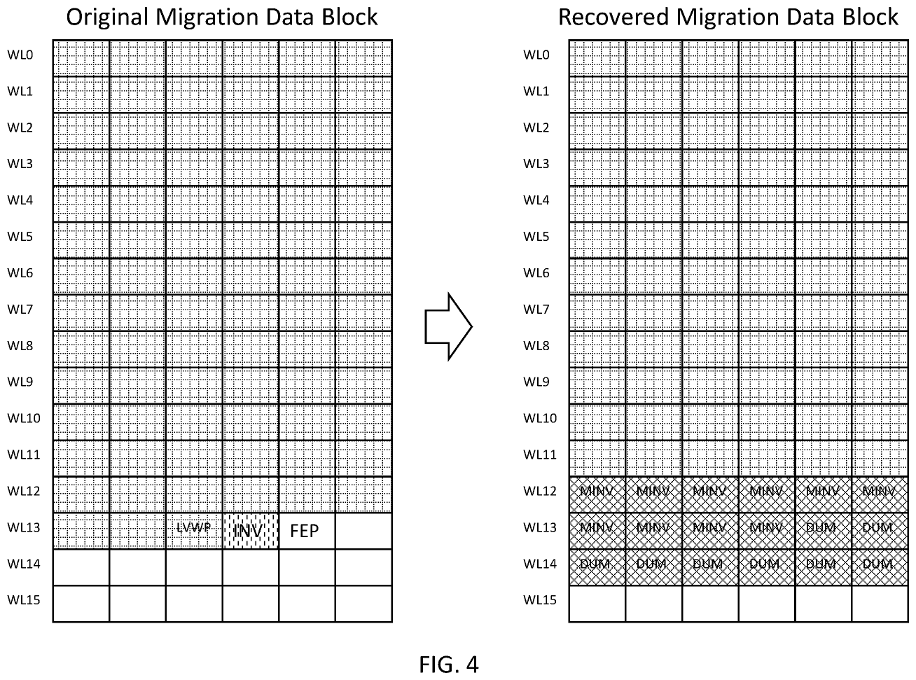

FIG. 4 shows a power loss recovery for a migration data block having one or more invalid, non-empty pages. The block to the left of the arrow in the figure represents an original migration data block before recovery by embodiments of the mechanisms described herein, and the block to the right of the arrow in the figure represents the same migration data block after recovery (the recovered migration data block) by the mechanisms described herein.

As illustrated, upon restoration of power, the original migration data block contains 13 word lines (WL0 through WL12) and three pages in WL13 of data that are valid. The LVWP is represented by LVWP in the figure. The FEP is represented by FEP in the figure. An invalid page is represented by INV in the figure. Although only one invalid page is shown in FIG. 2, any number of invalid pages could be present between the LVWP and the FEP, in some embodiments.

In recovering the migration data block, the mechanisms can: invalidate X word lines (WLs) of the block prior to the WL including the page immediately after the LVWP; invalidate all pages between the LVWP and the FEP; dummy program any empty pages in the WL including the last page before the FEP; and dummy program Y WLs of the block after the WL including the last page before the FEP. Any suitable values for X and Y (including one and zero) can be used in some embodiments, and these values can be technology dependent. For example, in some embodiments, X can be 3, 4, 5, 6, 7, or 8 and Y can be 3, 4, 5, 6, 7, or 8. In some embodiments, to subsequently confirm reliability of the block, all or a subset of the pages of the block can be read, and if any suitable number of read errors are encountered on valid WLs, the block can be abandoned and the original source copy of retained to potentially be migrated later.

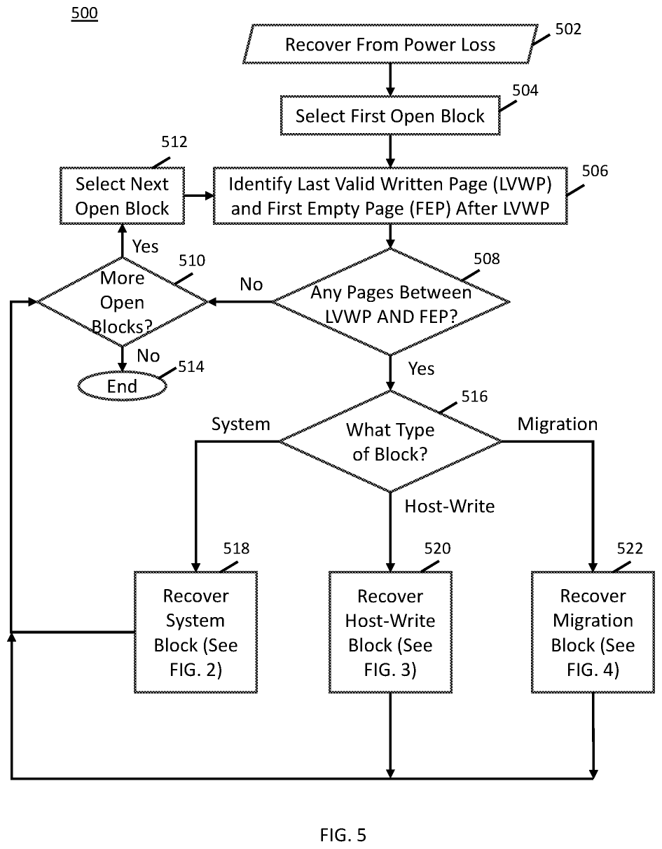

Turning to FIG. 5, an example 500 of a process for recovering an NVM device (such as an SSD) from a power loss in accordance with some embodiments is shown. Process 500 can be performed by any suitable device in some embodiments. For example, in some embodiments, process 500 can be performed by controller 104 of FIG. 1 or by one or more hardware processors on NVM devices 106, 108, and/or 110 of FIG. 1.

As illustrated, process 500 begins by recovering from a power loss at 502. Process 500 can determine that it has recovered from a power loss in any a suitable manner in some embodiments. For example, in some embodiments, process 500 can be initiated at 502 by any suitable circuit detecting an NVM device powering on when a non-volatile flag indicates that the NVM device was not powered down gracefully.

Next, at 504, process 500 can select a first open block of the NVM device. Any suitable block can be selected, and the block can be selected in any suitable manner in some embodiments.

Then, at 506, process 500 can identify the last valid written page (LVWP) and the first empty page (FEP) after the LVWP of the block. The LVWP can be determined in any suitable manner in some embodiments. For example, in some embodiments, LVWP can be determined by sequentially reading pages of the block in a forward or reverse order, or by searching the LVWP in any other suitable manner. The FEP can be determined in any suitable manner in some embodiments. For example, the FEP can be determined by sequentially reading each page after the LVWP to find the first empty page, in some embodiments.

At 508, process 500 can next determine if there are any pages between the L VWP and the FEP. This determination can be made in any suitable manner in some embodiments. For example, in some embodiments, this determination can be made by comparing a word line number and a page number of the LVWP and the FEP to determine if any pages exist between the two. Any pages between the LVWP and the FEP can be considered to be invalid, in some embodiments.

If it is determined at 508 that no pages exist between the LVWP and the FEP, then process 500 can indicate the selected block can be used and proceed to 510, at which it determines if there are more open blocks in the NVM device. If so, process 500 can select the next open block at 512 in any suitable manner and loop back to 506. Otherwise, process 500 can end at 514.

If it is determined at 506 that pages do exist between the LVWP and the FEP, then process 500 can determine what type of block is selected at 516. This determination can be made in any suitable manner in some embodiments. For example, in some embodiments, this determination can be made by reading data stored in the selected block which identifies the selected block's type. If it is determined at 516 that the block is a system block, then process 500 can recover the system block as described in connection with FIG. 2 above and then branch to 510. If it is determined at 516 that the block is a host-write data block, then process 500 can recover the host-write data block as described in connection with FIG. 3 above and then branch to 510. If it is determined at 516 that the block is a migration data block, then process 500 can recover the migration data block as described in connection with FIG. 4 above and then branch to 510.

In some embodiments, at least some of the above-described blocks of the process of FIG. 5 can be executed or performed in any order or sequence not limited to the order and sequence shown in and described in connection with the figure. Also, some of the above blocks of the process of FIG. 5 can be executed or performed substantially simultaneously where appropriate or in parallel to reduce latency and processing times in some embodiments. Additionally or alternatively, some of the above described blocks of the process of FIG. 5 can be omitted in some embodiments.

In some embodiments, any suitable computer readable media can be used for storing instructions for performing the functions and/or processes herein. For example, in some embodiments, computer readable media can be transitory or non-transitory. For example, non-transitory computer readable media can include media such as non-transitory forms of magnetic media (such as hard disks, floppy disks, and/or any other suitable magnetic media), non-transitory forms of optical media (such as compact discs, digital video discs, Blu-ray discs, and/or any other suitable optical media), non-transitory forms of semiconductor media (such as flash memory, electrically programmable read-only memory (EPROM), electrically erasable programmable read-only memory (EEPROM), and/or any other suitable semiconductor media), any suitable media that is not fleeting or devoid of any semblance of permanence during transmission, and/or any suitable non-transitory tangible media. As another example, transitory computer readable media can include signals on networks, in wires, conductors, optical fibers, circuits, any suitable media that is fleeting and devoid of any semblance of permanence during transmission, and/or any suitable transitory intangible media.

As can be seen from the description above, new mechanisms (which can include systems, methods, and media) for recovering NVM devices from power loss are provided. As described above, these mechanisms can reduce the delay experienced by an NVM device when recovering from a power loss in some embodiments.

Although the invention has been described and illustrated in the foregoing illustrative embodiments, it is understood that the present disclosure has been made only by way of example, and that numerous changes in the details of implementation of the invention can be made without departing from the spirit and scope of the invention, which is limited only by the claims that follow. Features of the disclosed embodiments can be combined and rearranged in various ways.

What is claimed is:

1. A system for recovering a non-volatile memory (NVM) device from a power loss, comprising:
memory; and
at least one hardware processor coupled to the memory and collectively configured to at least:
identify a first last valid written page (LVWP) of a first block of the NVM device;
identify a first first empty page (FEP) after the first LVWP of the first block;
determine that no pages exist between the first LVWP and the first FEP; and
in response to determining that no pages exist between the first LVWP and the first FEP, indicate that the first block can be used.

2. The system of claim 1, wherein the at least one hardware processor is further configured to:
identify a second LVWP of a second block of the NVM device;
identify a second FEP after the second LVWP of the second block;
determine that pages exist between the second LVWP and the second FEP; and
in response to determining that pages exist between the second LVWP and the second FEP, perform a recovery process on the second block.

3. The system of claim 2, wherein the recovery process comprises:
restoring the second block to a last known good state; and
invalidating a given non-zero number word lines of the second block after a last word line of the last known good state.

4. The system of claim 3, wherein the recovery process further comprises reconstructing data of non-empty pages of the second block after the last page of the last known good state.

5. The system of claim 2, wherein the recovery process comprises migrating all data from a first page of the second block through to and including the LVWP of the second block to a new data block.

6. The system of claim 2, wherein the recovery process comprises:
invalidating a first given non-zero number of word lines of the second block prior to and including a last page before the FEP; and
dummy programming a second given non-zero number of word lines of the second block starting at the FEP.

7. The system of claim 6, wherein the recovery process further comprises:
reading pages of the second block;
determining that at least a threshold number of read errors are encountered on valid word lines of the second block; and
creating a new block of data to replace the second block.

8. A method for recovering a non-volatile memory (NVM) device from a power loss, comprising:
identifying a first last valid written page (LVWP) of a first block of the NVM device;
identifying a first first empty page (FEP) after the first LVWP of the first block;
determining that no pages exist between the first LVWP and the first FEP using a hardware processor; and
in response to determining that no pages exist between the first LVWP and the first FEP, indicating that the first block can be used.

9. The method of claim 8, further comprising:
identifying a second LVWP of a second block of the NVM device;
identifying a second FEP after the second LVWP of the second block;
determining that pages exist between the second LVWP and the second FEP; and
in response to determining that pages exist between the second LVWP and the second FEP, performing a recovery process on the second block.

10. The method of claim 9, wherein the recovery process comprises:
restoring the second block to a last known good state; and
invalidating a given non-zero number word lines of the second block after a last word line of the last known good state.

11. The method of claim 10, wherein the recovery process further comprises reconstructing data of non-empty pages of the second block after the last page of the last known good state.

12. The method of claim 9, wherein the recovery process comprises migrating all data from a first page of the second block through to and including the LVWP of the second block to a new data block.

13. The method of claim 9, wherein the recovery process comprises:
invalidating a first given non-zero number of word lines of the second block prior to and including a last page before the FEP; and
dummy programming a second given non-zero number of word lines of the second block starting at the FEP.

14. The method of claim 13, wherein the recovery process further comprises:
reading pages of the second block;
determining that at least a threshold number of read errors are encountered on valid word lines of the second block; and
creating a new block of data to replace the second block.

15. A non-transitory computer-readable medium containing computer executable instructions that, when executed by a processor, cause the processor to perform a method for recovering a non-volatile memory (NVM) device from a power loss, the method comprising:
identifying a first last valid written page (LVWP) of a first block of the NVM device;
identifying a first first empty page (FEP) after the first LVWP of the first block;
determining that no pages exist between the first LVWP and the first FEP; and
in response to determining that no pages exist between the first LVWP and the first FEP, indicating that the first block can be used.

16. The non-transitory computer-readable medium of claim 15, wherein the method further comprises:
identifying a second LVWP of a second block of the NVM device;
identifying a second FEP after the second LVWP of the second block;
determining that pages exist between the second LVWP and the second FEP; and
in response to determining that pages exist between the second LVWP and the second FEP, performing a recovery process on the second block.

17. The non-transitory computer-readable medium of claim 16, wherein the recovery process comprises:
restoring the second block to a last known good state; and
invalidating a given non-zero number word lines of the second block after a last word line of the last known good state.

18. The non-transitory computer-readable medium of claim 17, wherein the recovery process further comprises reconstructing data of non-empty pages of the second block after the last page of the last known good state.

19. The non-transitory computer-readable medium of claim 16, wherein the recovery process comprises migrating all data from a first page of the second block through to and including the LVWP of the second block to a new data block.

20. The non-transitory computer-readable medium of claim 16, wherein the recovery process comprises:
invalidating a first given non-zero number of word lines of the second block prior to and including a last page before the FEP; and
dummy programming a second given non-zero number of word lines of the second block starting at the FEP.

21. The non-transitory computer-readable medium of claim 20, wherein the recovery process further comprises:
reading pages of the second block;
determining that at least a threshold number of read errors are encountered on valid word lines of the second block; and
creating a new block of data to replace the second block.
